(19) United States
(12) Patent Application Publication
(10) Pub. No.: US 2007/0102791 A1
(43) Pub. Date: May 10, 2007

(54) STRUCTURE OF MULTI-LAYER CRACK STOP RING AND WAFER HAVING THE SAME

(76) Inventor: Ping-Chang Wu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,982

(22) Filed: Nov. 7, 2005

(51) Int. Cl. H01L 29/06

(52) U.S. Cl. 257/618

(57) ABSTRACT

A multi-layer crack stop ring structure disposed between a die seal ring and a scribe line or disposed between a dual die seal ring is provided. The multi-layer crack stop ring structure does not occupy the space of the scribe line. In addition, the multi-layer crack stop ring structure is formed by stacking a plurality of crack stop rings having the same material or by interleavedly stacking multiple layers of the crack stop rings. The multi-layer crack stop ring structure can effectively prevent the damages such as chipping, delamination, or peeling from happening on the scribe line when performing the sawing process, such that a better die can be provided and the reliability of the packed object can be significantly improved.

### BACKGROUND OF THE INVENTION

1. Field of the Invention

The present invention relates to a wafer, and more particularly, to a wafer having a multi-layer crack stop ring structure. Specifically, the multi-layer crack stop ring structure surrounding the active circuit region is disposed between the active circuit region and the scribe line, so as to prevent the active circuit region from being damaged when sawing the wafer, which significantly improves the reliability of the packed object.

2. Description of the Related Art

Along with the continuous development of the new technology, the integrated circuits (IC) had been widely applied in our daily life. In general, the IC manufacturing process mainly includes three steps: the silicon wafer manufacturing process, the IC manufacturing process, and the IC packaging process. A die sawing process is performed as the first step of the IC packaging.

A silicon wafer generally comprises a plurality of horizontal scribe lines disposed parallelly with each other and a plurality of vertical scribe lines disposed vertically disposed with each other that are used to separate a plurality of dies. After the devices are completely fabricated on the wafer, then a diamond blade is used to saw the scribe line disposed along with the wafer, so as to obtain a plurality of dies. Specifically, various material layers are disposed on the wafer, during the wafer sawing operation, since the characteristic of the material layers are not the same, some damages such as chipping or peeling is occurred on the material layers on the scribe line.

In another conventional sawing technique, a laser grooving technique is introduced to replace the blade sawing. However, the laser grooving technique also has some problems. For example, during the wafer sawing operation, if the material layer disposed on the wafer contains a metal material, it is very hard to completely remove the metal material during the laser fusion operation. Accordingly, some debris still remains on the wafer, which stains the dies. In addition, a heat effect area is formed on the periphery of the scribe line during the laser grooving operation, and a big heat effect area will greatly impact the reliability of the dies. Moreover, the price of a general laser grooving equipment is about 2˜3 times higher than the price of the diamond blade equipment, which makes such method very expensive.

In addition, a method for manufacturing a crack stop structure on the device had been disclosed in U.S. Pat. No. 5,530,280. As shown in FIG. 1, two active circuit regions 110 and 120 are disposed on a substrate 100, and two dielectric layers 132 and 134 are formed on the substrate 100. Wherein, the dielectric layer 132 contains a metal contact 112 and two tungsten metal rings 142 and 152. The dielectric layer 134 contains a metal contact 116, three interconnect metals 114, 144, 154, and two tungsten metal rings 146 and 156 that have the hollow rings 145 and 155, respectively. The interconnect metals 118, 148, 158 are formed on the dielectric layer 134, respectively. Moreover, a scribe line region 160 is disposed between the interconnect metals 148 and 158.

The structure for preventing the active circuit region 110 from being impacted by the crack disclosed in the patent mentioned above comprises a tungsten metal ring 142, an interconnect metal 144, a tungsten metal ring 146, and an interconnect metal 148. In addition, the structure for preventing the active circuit region 120 from being impacted by the crack comprises a tungsten metal ring 152, an interconnect metal 154, a tungsten metal ring 156, and an interconnect metal 158. Since different material reacts differently to the same stress, the crack stop structure composed of different materials cannot rapidly and effectively prevent the active circuit region structure from being impacted by the crack during the horizontal scribe line region 160 sawing operation.

### SUMMARY OF THE INVENTION

Therefore, in an embodiment of the present invention, a multi-layer crack stop ring structure is provided. Wherein, the multi-layer crack stop ring structure disposed between a die seal ring and a scribe line or disposed between a dual die seal ring does not occupy the space of the scribe line.

In an alternative embodiment, an interleaved multi-layer crack stop ring structure is provided.

The multi-layer crack stop ring structure mentioned above can effectively avoid the damages such as chipping, peeling, or cracking on the scribe line. Accordingly, a better die can be obtained from the sawing operation, which significantly improves the reliability of the packed object.

In order to achieve the objects mentioned above, a wafer is provided by an embodiment of the present invention, and a plurality of dies is formed on the wafer. The dies are separated from each other by a plurality of scribe lines, and each die is surrounded by a scribe line mentioned above. Each die comprises an active circuit region, a die seal ring structure that surrounds the active circuit region, and a multi-layer crack stop ring structure surrounding the active circuit region. Here, the multi-layer crack stop ring structure is formed by stacking a plurality of hollow crack stop rings.

In the wafer of the embodiment mentioned above, wherein the multi-layer crack stop ring structure is disposed between the die seal ring structure and the scribe line or disposed between the die seal ring structure and the active circuit region.

In the wafer of the embodiment mentioned above, wherein the multi-layer crack stop ring structure is formed by stacking a plurality of crack stop rings having the same material.

In another embodiment of the present invention, the multi-layer crack stop ring structure in the wafer of the above embodiment is formed by interleavedly stacking the crack stop rings mentioned above.

In the wafer of the above embodiment, wherein the die seal ring structure is formed by interleavedly stacking a plurality of metal layers and contact VIAs. In addition, each metal layer and each VIA correspond to a crack stop ring.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic diagram of a conventional crack stop structure on the device.

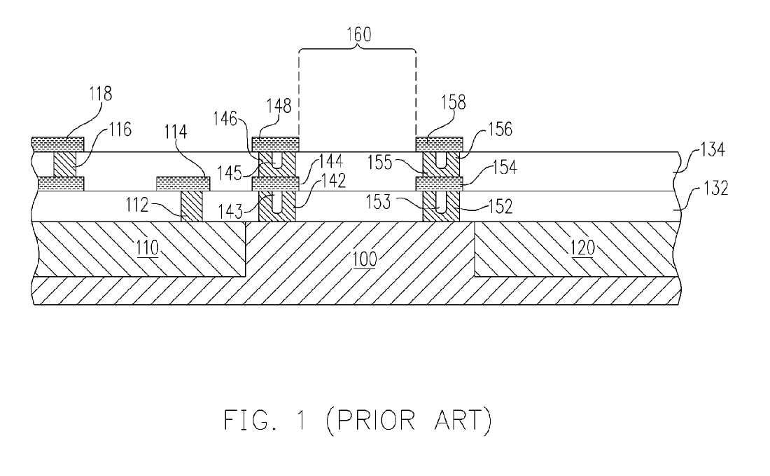

FIG. 2 a schematic diagram of a wafer with a plurality of dies formed thereon, and the dies are individually separated by the scribe lines.

FIG. 3 is schematically shows a diagram illustrating an interleaved multi-layer crack stop ring structure according to an embodiment of the present invention.

FIG. 4 schematically shows a diagram illustrating a multi-layer crack stop ring structure having the same material according to an embodiment of the present invention.

### DESCRIPTION PREFERRED EMBODIMENTS

In general, the device formed on the wafer usually comprises a plurality of material layers, and the material layers are also formed on the scribe line when the device is being fabricated. Therefore, during the wafer sawing operation, since each material layer on the scribe line has different material characteristics, some problems such as chipping or peeling easily happens on the scribe line. If the Low-k/Cu structure is going to be sawed, the problem of chipping and interlayer delamination becomes worse. When the scale of the device becomes smaller, the width of the scribe line becomes relatively smaller too, such that the problem of the crack formed in the sawing process penetrating into the operating metal or the active circuit region is more serious. Accordingly, the reliability of the packed object is deteriorated.

In an embodiment of the present invention, a multi-layer crack stop ring structure having the same material is provided. The multi-layer crack stop ring structure is disposed between the die seal ring and the scribe line. Specifically, the die seal ring is disposed on the periphery of the die and regarded as a protection wall on the periphery of the die to avoid the crack possibly occurred when sawing the die. In addition, the scribe line is disposed between the dies for separating each sawed die and regarded as a channel outside the protection wall of the die.

In another embodiment of the present invention, the multi-layer crack stop ring structure having the same material provided by the present invention is disposed between the dual die seal ring, wherein its physical layout is determined by the design requirement. The multi-layer crack stop ring structure having the same material provided by the present embodiment does not occupy the space of the scribe line. In addition, the present embodiment can effectively prevent the damage such as chipping, delamination, or peeling from happening on the scribe line when sawing the die.

In an alternative embodiment of the present invention, an interleaved multi-layer crack stop ring structure is provided. The multi-layer crack stop ring structure is disposed between the die seal ring and the scribe line. In another embodiment, the multi-layer crack stop ring structure is disposed between the dual die seal ring, and the physical layout is determined by the design requirement. The interleaved multi-layer crack stop ring structure having the same material provided by the present embodiment can effectively prevent the damage such as chipping, delamination, or peeling from happening on the scribe line. In addition, the interleaving parts described herein and after are interleavedly disposed between every two layers of the stack structure in the multi-layer crack stop ring. The interleaving parts can prevent the chipping generated during the sawing process from being torn from one of the layers or multiple layers for providing a better protection, and its detail is described in greater detail with referring to the accompanying drawings hereinafter.

In an alternative embodiment of the present invention, an interleaved multi-layer crack stop ring structure having the same material is provided for effectively preventing the damage such as chipping, delamination, or peeling from happening on the scribe line.

The principle of the present invention is described in greater detail with referring to the accompanying drawings. However, the scope of the present invention is not limited by it.

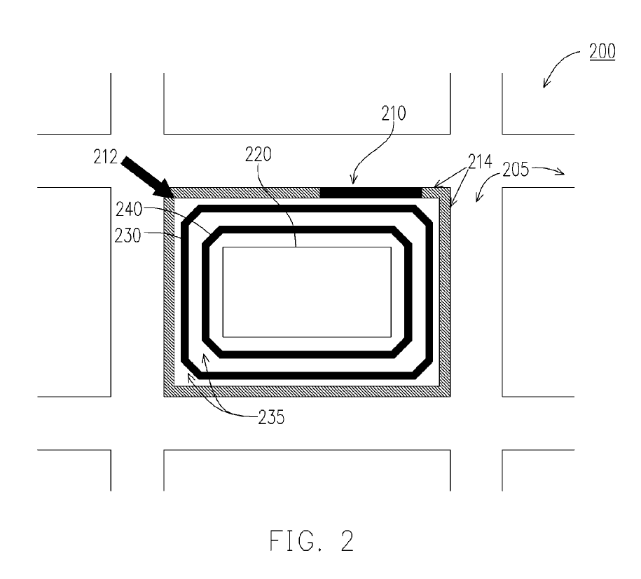

Referring to FIG. 2, a plurality of dies are formed on the wafer 200, wherein the dies are individually separated by the scribe line 205, such that the die can be formed independently after the sawing process. Although the description only describes the die 210, other dies also have the same structure as the die 210. In addition, the pad metals are disposed on the periphery of the active circuit region 220 inside the die 210, so as to form the dual die seal ring structure that comprises the die seal rings 230 and 240. The corner region 235 of the die seal rings 230 and 240 where a maximum stress occurs during the sawing process is generally bended to a certain angle of 45 degrees. Alternatively, in an embodiment of the present invention, it is also possible to use only one of the die seal rings 230 and 240. Even though, the present invention is not limited by it. The multi-layer crack stop ring structure having the same material or the interleaved multi-layer crack stop ring structure according to the embodiment of the present invention is formed between the scribe line 205 and the dual die seal ring 230 and 240, and it is near the scribe line edge 214.

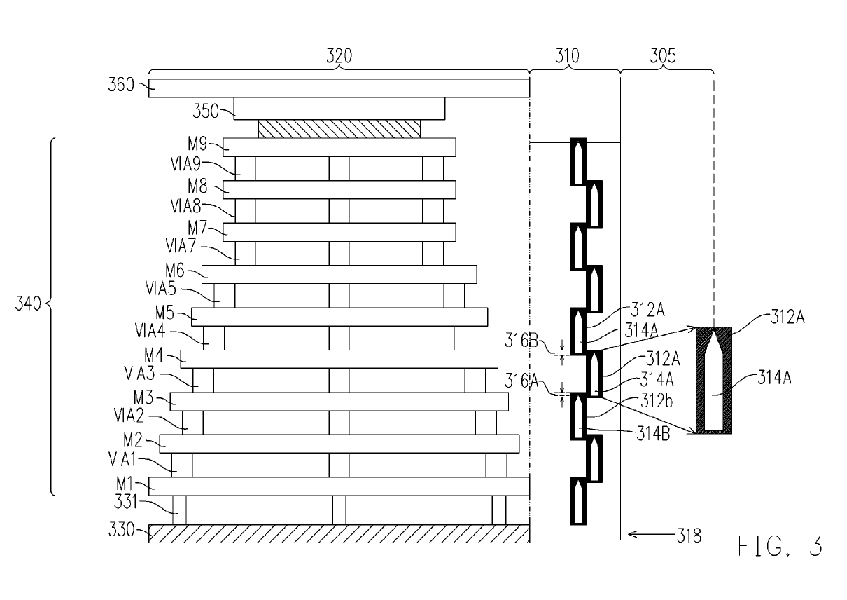

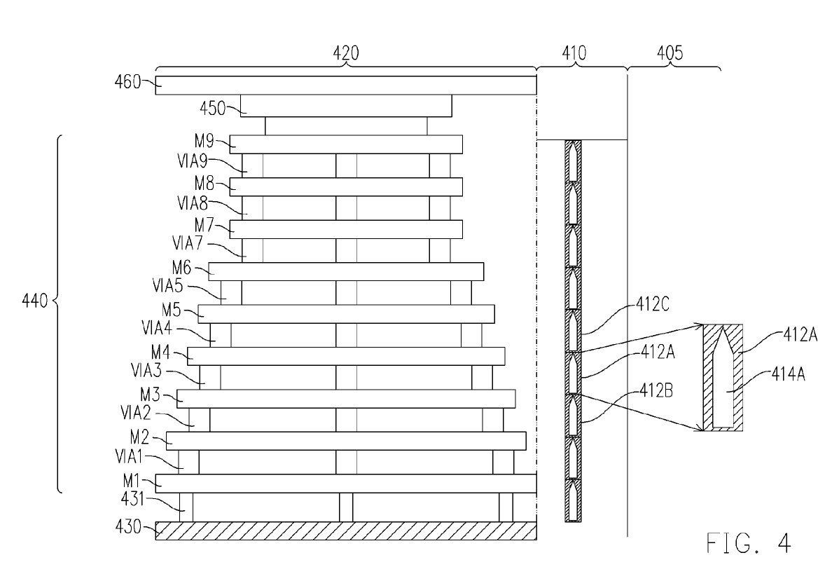

The die seal ring structure and the multi-layer crack stop ring structure according to an embodiment of the present invention are described in greater detail with referring to FIGS. 3 and 4 hereinafter.

FIG. 3 schematically shows a diagram illustrating an interleaved multi-layer crack stop ring structure according to an embodiment of the present invention. The crack stop ring structure region 310 is disposed between the die seal ring region 320 and the scribe line 305. The interleaved multi-layer crack stop ring structure is formed by stacking multiple layers of the crack stop rings, and the stack structure is formed at the same time when the die seal ring is formed on the die seal ring region 320. Therefore, the interleaved multi-layer crack stop ring structure may have the same material. Wherein, the die seal ring is formed at the same time when the metal layers M1˜M9 and the VIAs VIA1˜VIA8 between each two layers are formed on the die seal ring region 320. The die seal ring disposed on the substrate 330 is connected to a contact 331. Then, an aluminum (Al) metal layer 350 is disposed thereon, and a passivation layer 360 is disposed on the aluminum (Al) metal layer 350.

The overlaid parts between each two neighboring crack stop rings are referred to as the interleaved structure. For example, in the stack structure of the neighboring crack stop rings 312B, 312A, and 312C, when viewing from the direction marked by the arrow 318 in the diagram, the overlaid parts 316A and 316B are interleavedly disposed. During the sawing process, the interleaved multi-layer crack stop ring structure can be rapidly cut off by the mechanical stress generated by it, such that the chipping is avoided and a better protection is provided.

In the interleaved multi-layer crack stop ring structure of the present embodiment, each crack stop ring has a hollow ring. In one embodiment, some portions of the hollow rings are overlaid in the direction marked by the arrow 318. In other words, in the stack structure of the neighboring crack stop rings 312B, 312A, and 312C, some portions of the hollow rings 314B, 314A, and 314C are overlaid in the direction marked by the arrow 318. Accordingly, it can more effectively avoid the clipping and provide a better protection.

FIG. 4 schematically shows a diagram illustrating a multi-layer crack stop ring structure having the same material according to an embodiment of the present invention. The crack stop ring structure region 410 is disposed between the die seal ring region 420 and the scribe line 405. The multi-layer crack stop ring structure is formed by directly stacking multiple layers of the crack stop rings, and the stack structure is formed at the same time when the die seal ring is formed on the die seal ring region 420. Therefore, the multi-layer crack stop ring structure may have the same material. Wherein, the die seal ring is formed at the same time when the multiple metal layers and the VIAs between each two layers are interleavedly formed on the die seal ring region 420. The die seal ring disposed on the substrate 430 is connected to a contact 431. Then, an aluminum (Al) metal layer 450 is disposed thereon, and a passivation layer 460 is disposed on the aluminum (Al) metal layer 450. Each two neighboring crack stop rings are disposed interleavedly as the stack structure of the neighboring crack stop rings 412B, 421A, and 412C shown in the diagram. During the sawing process, the multi-layer crack stop ring structure can be rapidly cut off by the mechanical stress generated by it, such that the chipping is avoided and a better protection is provided. In the multi-layer crack stop ring structure of the present embodiment, each crack stop ring has a hollow ring. For example, the crack stop ring 412A has a hollow ring 414A, which avoids the clipping more effectively and provides a better protection.

In summary, a multi-layer crack stop ring structure disposed between a die seal ring and a scribe line or disposed between a dual die seal ring is provided by the present invention. The multi-layer crack stop ring structure provided by the present invention does not occupy the space of the scribe line, and can effectively prevent the damages such as chipping, delamination, or peeling from happening on the scribe line when performing the sawing process, such that a better die can be provided and the reliability of the packed object can be significantly improved.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A wafer having a plurality of dies separated by a plurality of scribe lines, wherein each die is surrounded by a scribe line, and each die comprises an active circuit region, a die seal ring structure disposed on the periphery of the active circuit region, and a multi-layer crack stop ring structure surrounding the active circuit region, moreover, the multi-layer crack stop ring structure is formed by stacking a plurality of hollow crack stop rings.

2. The wafer of claim 1, wherein the multi-layer crack stop ring structure is disposed between the die seal ring structure and the scribe line.

3. The wafer of claim 1, wherein the multi-layer crack stop ring structure is disposed between the die seal ring structure and the active circuit region.

4. The wafer of claim 1, wherein the multi-layer crack stop ring structure is formed by stacking a plurality of crack stop rings having the same material.

5. The wafer of claim 1, wherein the multi-layer crack stop ring structure is formed by interleavedly stacking the crack stop rings having the same material.

6. The wafer of claim 1, wherein the die seal ring structure is composed of a single die seal ring.

7. The wafer of claim 1, wherein the die seal ring structure is composed of a dual die seal ring.

8. The wafer of claim 1, wherein the die seal ring structure is formed by interleavedly stacking a plurality of metal layers and VIAs, and each metal layer and VIA correspond to a crack stop ring.

9. A multi-layer crack stop ring structure disposed on a die, wherein each die is surrounded by a scribe line, and each die comprises an active circuit region and a die seal ring structure disposed on the periphery of the active circuit region, wherein the multi-layer crack stop ring structure surrounds the periphery of the active circuit region, and the multi-layer crack stop ring structure is formed by stacking a plurality of hollow crack stop rings.

10. The multi-layer crack stop ring structure of claim 9, wherein the multi-layer crack stop ring structure is disposed between the die seal ring structure and the scribe line.

11. The multi-layer crack stop ring structure of claim 9, wherein the multi-layer crack stop ring structure is disposed between the die seal ring structure and the active circuit region.

12. The multi-layer crack stop ring structure of claim 9, wherein the multi-layer crack stop ring structure is formed by stacking a plurality of crack stop rings with the same material.

13. The multi-layer crack stop ring structure of claim 9, wherein the multi-layer crack stop ring structure is formed by interleavedly stacking the crack stop rings with the same material.

14. The multi-layer crack stop ring structure of claim 9, wherein the die seal ring structure is formed by interleavedly stacking a plurality of metal layers and VIAs, and each metal layer and VIA correspond to a crack stop ring.
